(19) United States
(12) Patent Application Publication
(10) Pub. No.: US 2005/0170598 A1
(43) Pub. Date: Aug. 4, 2005

(54) Silicided amorphous polysilicon - metal capacitor

(76) Inventors: Gregory Eric Howard, Dallas, TX (US); Leland Swanson, McKinney, TX (US)

Correspondence Address: TEXAS INSTRUMENTS INCORPORATED, P O BOX 655474, M/S 3999, DALLAS, TX, 75265, US

(21) Appl. No.: 10/767,390

(22) Filed: Jan. 29, 2004

(51) Int. Cl. H01G 4/008; H01L 21/20

(52) U.S. Cl. 438/396

(57) ABSTRACT

A silicided amorphous polysilicon-metal capacitor is formed using a standard process except that the exposed surface of the polycrystalline silicon is transformed into amorphous polysilicon before the silicidation of the polysilicon layer to form the bottom plate of the capacitive element. Transforming the polycrystalline silicon to amorphous polysilicon at the surface renders the top surface of the polysilicon substantially smooth compared to that of the polycrystalline silicon. This in turn renders the surface of the silicide layer, which forms the bottom plate of the capacitor and is formed by the silicidation of the polysilicon, to be substantially smooth as well. Thus, the likelihood of stress points being formed in the dielectric layer of the capacitor is substantially reduced, increasing yield and reliability and permitting a reduction in the thickness which leads to a greater value of capacitance per unit area. The polycrystalline silicon can be rendered amorphous through implantation of a neutral species prior to the silicidation of the polysilicon to form the silicide layer that is used for the bottom plate of the capacitive element.

### BACKGROUND

There is a never-ending motivation for circuit device and process designers to reduce the cost of manufacturing integrated circuits and to improve their reliability. This can also be said for the capacitive elements of such circuits specifically.

A standard polysilicide to metal capacitive element 10, currently employed in integrated circuits is illustrated in FIG. 1. Typically, the capacitor 10 is built on a silicon substrate 12 which is typically a silicon wafer (along with any number of other circuit elements that form constituents of an integrated circuit). The substrate 12 may include a buried layer implant as is known in the art. An oxide layer 18 is then formed over the substrate 12, which isolates the capacitive element 10 from the substrate 12 and other circuit elements that may be built on the substrate 12. A polysilicon layer 14 is then formed over the oxide layer 18. A metal layer (not shown) is deposited over the poly layer 14 and then the wafer is subjected to an annealing process which causes the metal to combine with the polysilicon 14 to produce a silicided polysilicon layer 19 that is highly conductive. The silicided poly layer 19 thus forms one of the two conductive plates of the capacitor.

Another oxide layer 20 is then typically formed over the silicide layer 19, which acts as the dielectric for the capacitor 10. Finally, a layer of metal 22 is deposited onto the dielectric oxide layer 20, which forms the second plate of the capacitor 10. A contact 24 is then typically formed by which the plate of capacitor 10 formed by metal layer 22 may be accessed for making electrical connection to one side of the capacitor 10. Those of skill in the art will recognize that other metallization layers may be further built on top of the capacitor 10 by using additional oxide layers to isolate it from the metal layers (not shown). Moreover, an additional contact is also typically created for access to the plate formed by the silicide layer 19 that is also not shown in FIG. 1. The techniques by which the layers are created that are described as part of a standard poly-metal capacitor such as that shown in FIG. 1 are well known to those of skill in the art and therefore will not be described in any further detail.

One problem associated with the capacitive element 10 of FIG. 1 is that the polysilicon crystals at the top surface of the polysilicon layer 14 can be quite large and highly non-planar. Thus, the top surface 16 of the polysilicide layer 19 has this same non-planar quality after the annealing step during which the silicide layer 19 is grown at the top surface of the polysilicon layer 14. When the dielectric oxide layer 20 is deposited on top of the polysilicide layer 19, the highly non-planar character of the surface produces inhomogeneities in the oxide film and electric field within the capacitor. The electric field is more intense at points protruding from the surface, where coincidentally, the film thickness is typically reduced. Oxide failure is more likely at these locations. Additionally, the local film stress varies, further weakening the film. The high density of weak points in the film presents a long-term circuit reliability problem, as well as short-term yield problems that drive up the cost of manufacture.

To mitigate this problem, the dielectric oxide layer is typically made thicker than would otherwise be desirable. For a given capacitance value, this requires that the capacitor cover more surface area of the substrate, which also increases the die size and thus also drives up the cost of manufacture.

### SUMMARY

This disclosure describes processing methods and circuit structures that address one or more of the issues noted above. In at least one embodiment, a standard process for building a silicided polysilicon capacitive element is employed, except that prior to siliciding a polysilicon layer, the top surface of the polysilicon layer is rendered amorphous to reduce the size of the polysilicon crystals thereby producing a substantially planar surface. In at least one embodiment, a capacitor built in accordance with an embodiment of the method of the invention has a bottom plate that is a silicided polysilicon layer having a substantially planar surface in contact with a dielectric layer.

### BRIEF DESCRIPTION OF THE DRAWINGS

For a detailed description of embodiments of the invention, reference will now be made to the accompanying drawings in which:

FIG. 1 is a cross-sectional view of a portion of a semiconductor circuit that shows a standard polysilicide to metal capacitive element structure manufactured in accordance with a prior art process;

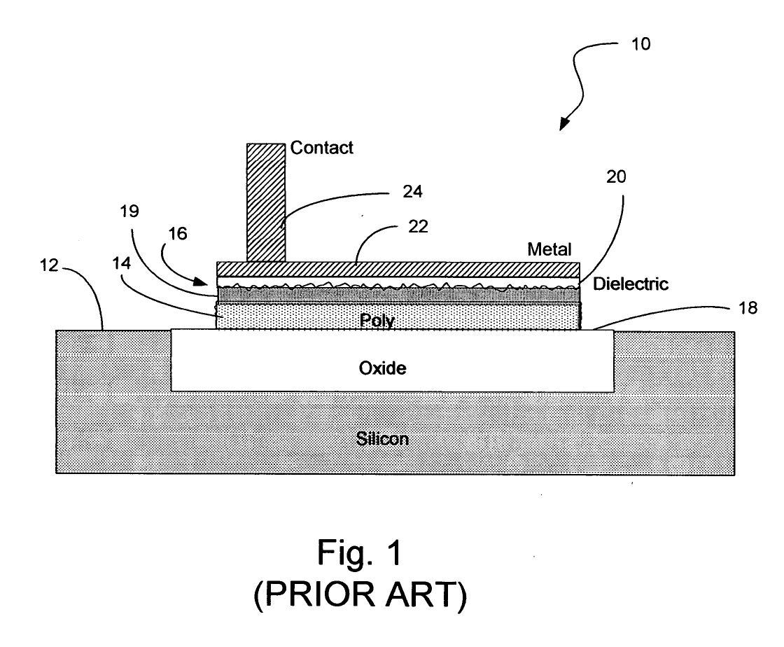

FIG. 2 is a cross-sectional view of a portion of a semiconductor circuit that shows a preparation of silicon starting material in the process of building a silicided poly amorphous silicon-metal capacitor in accordance with an embodiment of the invention;

FIG. 3 is a cross-sectional view of a portion of a semiconductor circuit that shows formation of an isolation field oxide layer in the process of building a silicided poly amorphous silicon-metal capacitor in accordance with an embodiment of the invention;

FIG. 4 is a cross-sectional view of a portion of a semiconductor circuit that shows the formation of a polysilicon layer in the process of building a silicided poly amorphous silicon-metal capacitor in accordance with an embodiment of the invention;

FIG. 5 is a cross-sectional view of a portion of a semiconductor circuit that shows the results of an amorphizing implant of the polysilicon layer in the process of building a silicided poly amorphous silicon-metal capacitor in accordance with an embodiment of the invention;

FIG. 6a is a cross-sectional view of a portion of a semiconductor circuit that shows the formation of a metal layer to be used in forming a silicide layer in the process of building a silicided poly amorphous silicon-metal capacitor in accordance with an embodiment of the invention;

FIG. 6b is a cross-sectional view of a portion of a semiconductor circuit that illustrates annealing the metal layer of FIG. 6a to complete the formation of the silicide layer in the process of building a silicided poly amorphous silicon-metal capacitor in accordance with an embodiment of the invention.

FIG. 7 is a cross-sectional view of a portion of a semiconductor circuit that shows deposition of a capacitor dielectric layer in the process of building a silicided poly amorphous silicon-metal capacitor in accordance with an embodiment of the invention;

FIG. 8 is a cross-sectional view of a portion of a semiconductor circuit that shows deposition, masking and etching of a top capacitor metal layer in the process of building a silicided poly amorphous silicon-metal capacitor in accordance with an embodiment of the invention;

FIG. 9 is a cross-sectional view of a portion of a semiconductor circuit that shows formation of a metallization stack in the process of building a silicided poly amorphous silicon-metal capacitor in accordance with an embodiment of the invention;

FIG. 10 is a flow diagram that describes a process flow for building a silicided poly amorphous silicon-metal capacitor in accordance with an embodiment of the invention.

### NOTATION AND NOMENCLATURE

Certain terms are used throughout the following description and in the claims to refer to particular process steps, process materials and structures resulting therefrom. As one skilled in the art will appreciate, those skilled in the art may refer to a process, material or resulting structure by different names. This document does not intend to distinguish between components, materials or processes that differ in name but not function. In the following discussion and in the claims, the terms “including” and “comprising” are used in an open-ended fashion, and thus should be interpreted to mean “including, but not limited to . . . .”

### DETAILED DESCRIPTION

The following discussion is directed to various embodiments of the invention. Although one or more of these embodiments may be preferred, the embodiments disclosed should not be interpreted as or otherwise used to limit the scope of the disclosure, including the claims, unless otherwise specified. In addition, one skilled in the art will understand that the following description has broad application, and the discussion of any embodiment is meant only to be exemplary of that embodiment, and not intended to intimate that the scope of the disclosure, including the claims, is limited to that embodiment.

For example, there are a number of ways known to those of skill in the art to produce a particular layer in a semiconductor device, such as ion implantation, chemical vapor deposition, diffusion and the like. Moreover, such layers may contain various chemical constituents that produce similar result and purpose, although some species may be better suited than others depending upon the context and the particular process flow employed. While this disclosure may endeavor to note such alternatives in technique and chemical constituency, under no circumstances should any such list be deemed exhaustive nor should embodiments disclosed herein be limited to only those noted examples. Finally, parametric information has been disclosed for some of the processing steps disclosed herein to aid one of ordinary skill to practice the invention. Wherever possible, such parametric data is provided in typical ranges, but in no way should the specification of any such range be construed as an attempt to limit the range in which various embodiments of the invention are intended to operate or be processed unless explicitly stated otherwise.

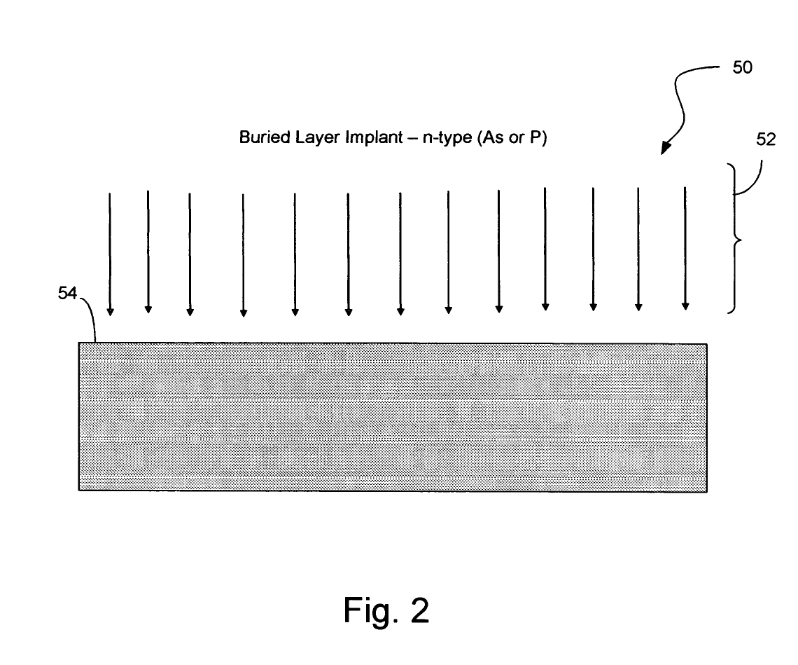

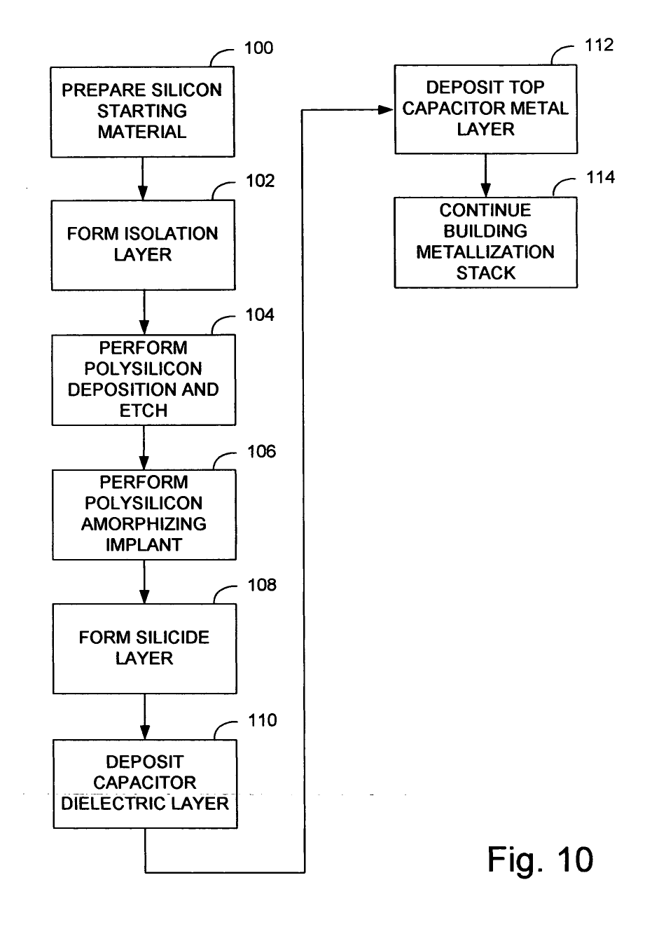

Referring now to FIG. 2, a cross-sectional view of a portion of a semiconductor circuit that is being processed to form a capacitive element 50 in accordance with an embodiment of the invention is shown. First, a silicon substrate 54 starting material is prepared in accordance with one or more processing steps known in the art that may include a buried layer implant 52. If the starting material for the substrate 54 is n-type, the buried layer implant 52 will also be n-type (typically Arsenic (As) or Phosphorous (P)). This set of processing functions is represented in the process flow diagram of FIG. 10 as Prepare Silicon Starting Material 100.

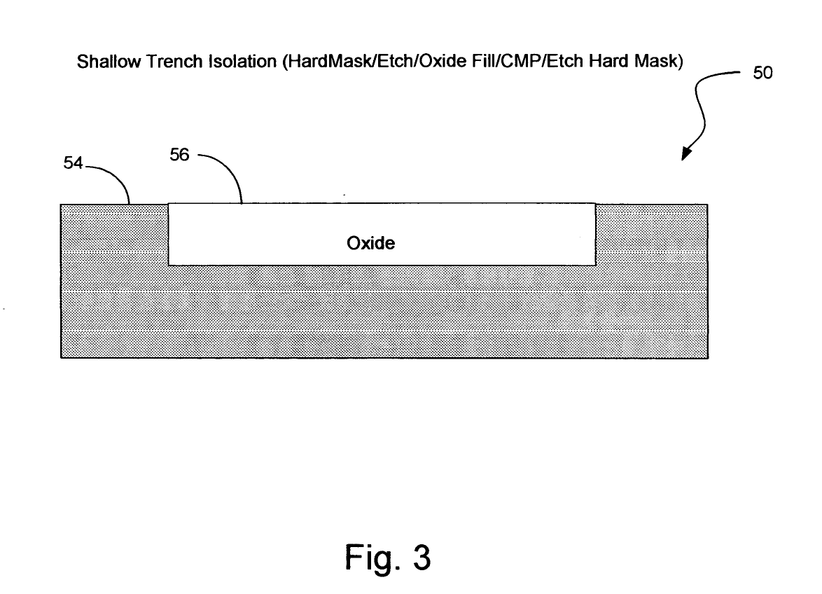

Referring to FIG. 3, an isolation layer 56 is formed on the substrate 54 to isolate the capacitor from any other devices that will also be formed in the substrate 54. The isolation layer 56 can be created in accordance with one or more processing functions known in the art that may include forming a shallow trench isolation (STI) field oxide 56. The location of the isolation layer 56 is first typically determined through a masking process by which the mask permits the silicon to be etched below the surface to form a trench where the isolation 56 is to be located. A material suitable for electric isolation, such as a field oxide layer 56, is deposited over the exposed surface of the substrate 54 to fill in the trench. The surface undergoes a chemical/mechanical polish (CMP) and the masking layer (not shown) is then etched from the surface of the substrate 54. This set of processing functions is represented in the process flow diagram of FIG. 10 as Form Isolation Layer 102.

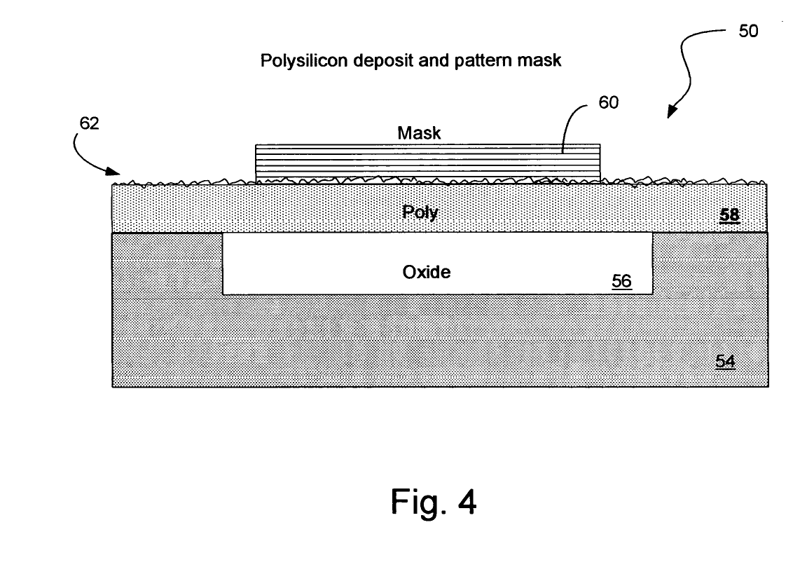

With reference to FIG. 4, a polysilicon layer 58 is then deposited and masked as part of the process of forming the bottom plate of the capacitor structure 50. The top surface 62 of the polysilicon layer 58 is typically comprised of large crystals. As previously discussed, these large crystals can create stress points in the relatively thin capacitor dielectric layer which is typically deposited over the top surface 62 of the polysilicon layer after it has been silicided. Points of high physical stress are known to produce weakened oxide dielectric, and high electrical field stress will combine to limit the maximum voltage capability of the structure 50. These processing functions are represented in the process flow diagram of FIG. 10 as Perform Polysilicon Deposition and Etch 104.

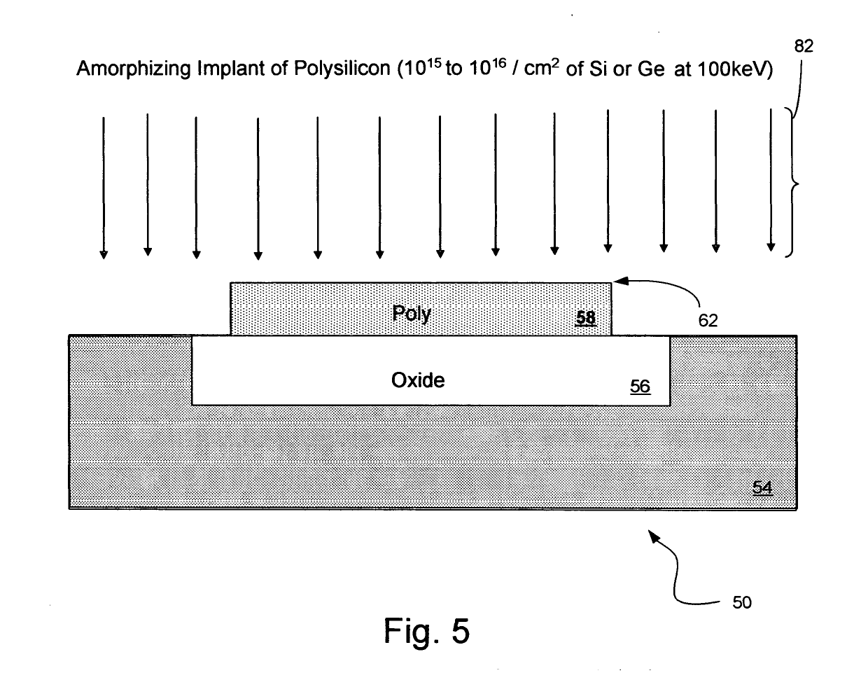

In FIG. 5, the result of the polysilicon etch process is visible in that the polysilicon layer 58 of the capacitive structure 50 is now aligned over the isolation oxide 56. FIG. 5 also illustrates that the exposed surfaces of the capacitive structure 50 are subjected to an ion implantation of a neutral species, such as silicon (Si), Germanium (Ge) or the like. In an embodiment of the invention, the implant should achieve a depth of about 500 to 1000 Angstroms and a dose on the order of about 10¹⁵/cm² to 10¹⁶/cm². An implant energy of about 100 KeV should be sufficient to achieve the desired depth at the desired dosage. This implantation process ensures that the surface 62 of the polysilicon layer 58 is transformed into amorphous silicon. Transforming the surface 62 into amorphous silicon causes it to be substantially smoother. This processing function is represented in the process flow diagram of FIG. 10 as Perform Polysilicon Amorphizing Implant 106.

In another embodiment, the transformation of the surface 62 to amorphous polysilicon may be achieved through a plasma bombardment of surface 62. An inert heavy atom carrier gas such as argon, krypton, xenon, and the like can be introduced into a plasma chamber. The plasma chamber can be similar to that used in a plasma enhanced chemical vapor deposition PECVD chamber. In another embodiment, an etch chamber may be used to achieve high plasma densities at fairly high pressures. The process would work by using the ion bombardment of the surface to disrupt the lattice structure (similar to the implant). Those of skill in the art will recognize that there may be other means by which the transformation of surface 62 to amorphous polysilicon may be accomplished without exceeding the intended scope of this disclosure.

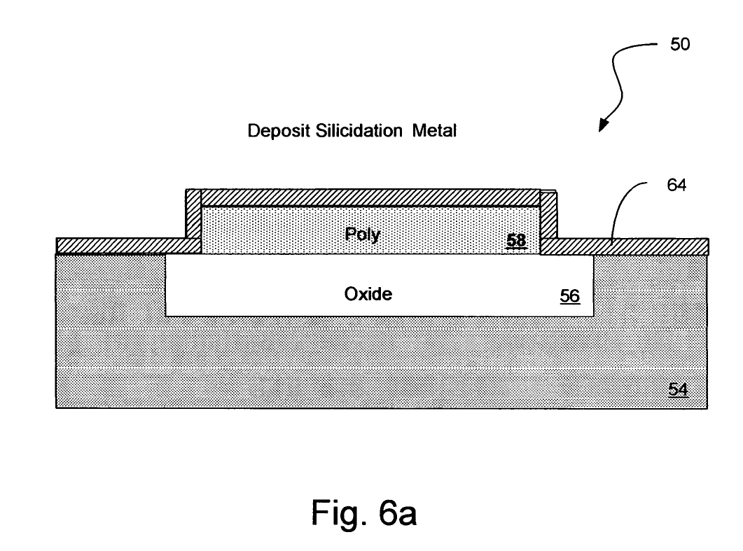

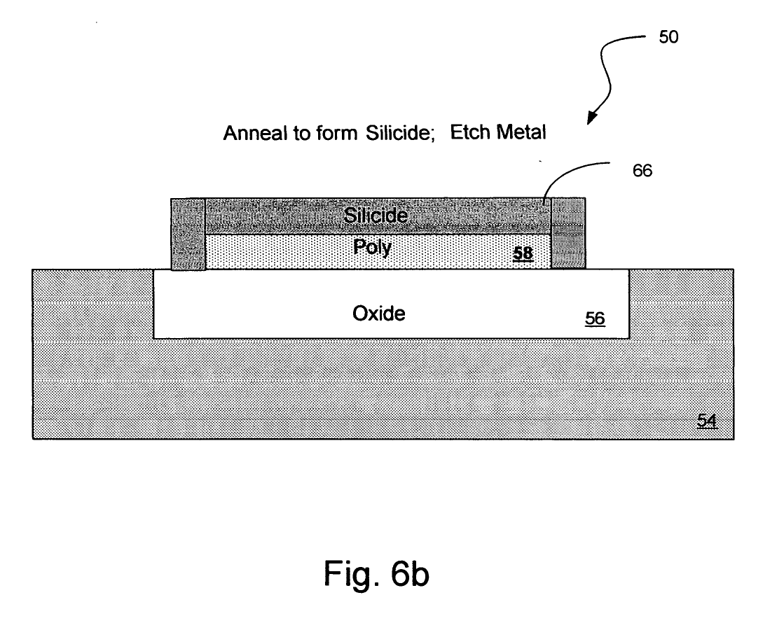

FIG. 6a illustrates the deposition of a metal layer 64 as a first step in the silicidation of the polysilicon layer 58 to ultimately form a silicide layer at the top surface of the polysilicon layer 58. FIG. 6b shows that the capacitive structure 50 is subjected to an annealing process that causes the metal layer 64 to combine with the polysilicon layer 68 to produce a silicide layer 66. The metal is then masked and etched to leave the silicide layer 66. The polysilicon layer 58 and silicide layer 66 form the bottom plate of the capacitive structure 50. Because the top surface 62, FIG. 5 of the polysilicon layer 58 had been previously rendered amorphous by the implant, the silicide layer 66 is also rendered substantially smooth. The foregoing processing functions are represented in the process flow diagram of FIG. 10 as Form Silicide Layer 108.

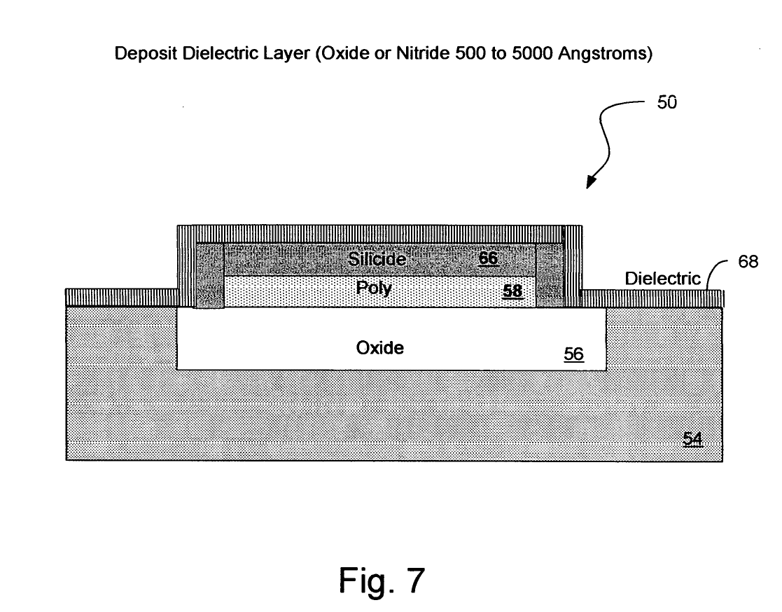

FIG. 7 illustrates the deposition of a dielectric layer 68. The dielectric layer can be formed of oxide or nitride for example, the thickness ranging between about 500 to 1000 Angstroms. Because the top surface of the silicide layer 66 has been rendered substantially smooth as a result of the amorphizing implant, the likelihood of stress points at the interface between the silicide layer and the dielectric layer has been substantially reduced. Thus, the thickness of the dielectric may be significantly reduced, thereby reducing the surface area of the top and bottom plates of the capacitive element for a given capacitance value (i.e. it increases substantially the capacitance per unit area). This resulting reduction in die area for a given capacitive element 50 decreases the cost of manufacture of integrated circuits employing the capacitive element of the invention. Moreover, variation in the bottom plates is also substantially reduced, which also improves circuit yields and thereby reduces the cost of manufacture. The foregoing processing functions are represented in the process flow diagram of FIG. 10 as Deposit Capacitor Dielectric Layer 110.

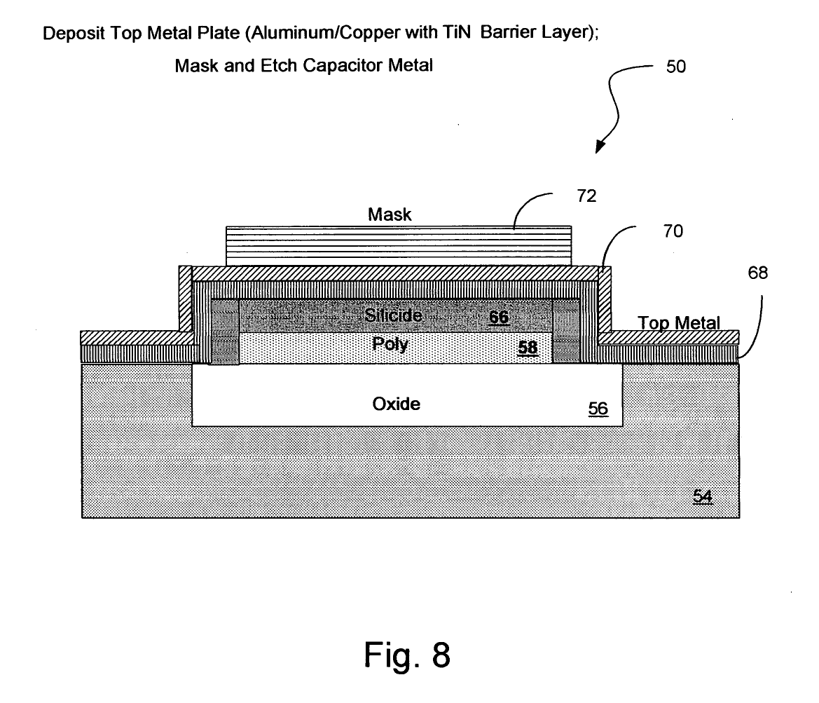

FIG. 8 illustrates the deposition of a top metal layer 72, which is patterned to produce mask 72 and then etched to form the top plate of the capacitor (not shown). The top metal layer 72 may be formed of an aluminum/copper with a titanium nitride (TiN) barrier layer or equivalent materials. This processing function is represented in the process flow diagram of FIG. 10 as Deposit Top Capacitor Metal Layer 112.

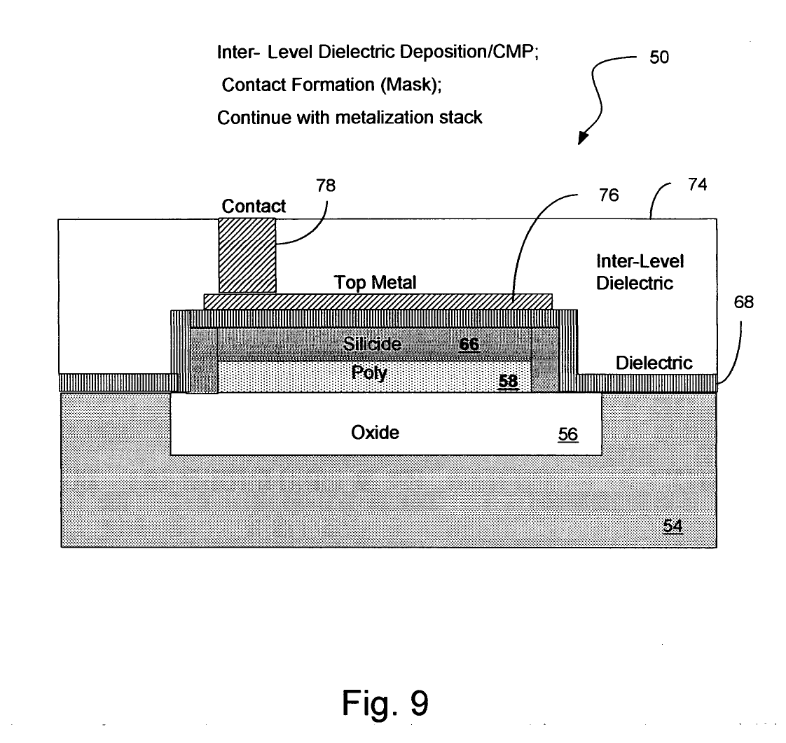

And finally, FIG. 9 illustrates the result of the metal etch to form the top metal plate 76 of the capacitive element 50. FIG. 9 also illustrates the process of forming a metallization stack on top of the capacitive element 50. First, an interlevel dielectric layer 74 is deposited over the capacitive element 50 to isolate the top metal plate 74 from the metal interconnect (not shown) that will be later formed and running over the top the capacitive element. A contact 78 is formed so that the top metal plate may be conductively connected to one or more of the interconnect lines running over the top of the capacitive element 50. Those of skill in the art will recognize that a contact may also be formed to contact the bottom plate of capacitive element 50, which is not shown. One or more levels of interconnect lines (not shown) may then be formed over capacitive element 50. The foregoing processing functions are represented in the process flow diagram of FIG. 10 as Form Metallization Stack 114.

In summary, embodiments of the invention employ a standard process flow for creating a capacitive element, but create amorphous polysilicon to smooth out the surface of the polysilicon before performing the silicidation of the polysilicon. This renders the silicide layer formed by the silicidation of the polysilicon to be substantially smooth relative to the surface of the silicide layer of the standard process. The smooth silicide surface substantially reduces the likelihood that stress points will be created at the interface between the silicide layer and the capacitor dielectric, thereby substantially reducing the likelihood that cracks will form in the dielectric leading to the plates being shorted together. Not only does this improve the yield and reliability of the devices (and therefore of any integrated circuit in which these capacitive elements are employed), but it permits the dielectric to made substantially thinner, which increases the amount of capacitance per unit area of the silicon employed which also decreases the cost of manufacture. In an embodiment of the invention, the polycrystalline silicon can be transformed into amorphous polysilicon using an implantation of a neutral species.

1. A method of producing a silicided amorphous polysilicon to metal capacitor, said method comprising the steps of:
forming a first plate of the capacitor, said forming further comprising:
depositing a layer of polysilicon over an isolation layer, the isolation layer being formed on a substrate;
amorphizing the polysilicon layer; and
siliciding the exposed surface of the polysilicon layer;
depositing a dielectric over the first plate; and
forming a second plate of the capacitor over the dielectric layer.

2. The method of producing a silicided amorphous polysilicon to metal capacitor as recited in claim 1 wherein said amorphizing further comprises implanting a neutral species in the polysilicon layer.

3. The method of producing a silicided amorphous polysilicon to metal capacitor as recited in claim 2 wherein the neutral species is silicon.

4. The method of producing a silicided amorphous polysilicon to metal capacitor as recited in claim 2 wherein the neutral species is germanium.

5. The method of producing a silicided amorphous polysilicon to metal capacitor as recited in claim 2 wherein dosage of the neutral species resulting from said implanting is substantially between 10¹⁵ per cm² and 10¹⁶ per cm² to a depth of about 500 to 1000 Angstroms.

6. The method of producing a silicided amorphous polysilicon to metal capacitor as recited in claim 2 wherein the energy of the implant is about 100 KeV.

7. The method of producing a silicided amorphous polysilicon to metal capacitor as recited in claim 1 wherein the exposed surface of the amorphized polysilicon is substantially smooth relative to polycrystalline silicon.

8. The method of producing a silicided amorphous polysilicon to metal capacitor as recited in claim 1 wherein said amorphizing further comprises exposing the polycrystalline silicon to an ion bombardment produced in a plasma enhanced chemical vapor deposition (PECVD) chamber.

9. The method of producing a silicided amorphous polysilicon to metal capacitor as recited in claim 8 wherein the ion bombardment is generated from a heavy ion carrying gas, including argon, krypton, or xenon.

10. The method of producing a silicided amorphous polysilicon to metal capacitor as recited in claim 1 wherein said amorphizing further comprises exposing the polycrystalline silicon to an ion bombardment produced in an etch chamber.

11. A silicided amorphous polysilicon to metal capacitor comprising:
a first plate comprising a top portion that is silicided amorphous polysilicon, the remaining portion of the first plate comprising polycrystalline silicon;
a second plate comprising a metal layer; and
a dielectric layer formed between the first and second plates.

12. The silicided amorphous polysilicon to metal capacitor as recited in claim 11 wherein the top surface is substantially smoother relative to the remaining portion.

13. The silicided amorphous polysilicon to metal capacitor as recited in claim 111 wherein the first plate is formed on an isolation layer.

14. The silicided amorphous polysilicon to metal capacitor as recited in claim 11 wherein the amorphous silicon of the first plate is formed by implanting a neutral species into substantially into the top surface of a polycrystalline silicon layer.

15. The silicided amorphous polysilicon to metal capacitor as recited in claim 14 wherein the neutral species is silicon.

16. The silicided amorphous polysilicon to metal capacitor as recited in claim 14 wherein the neutral species is germanium.

17. The silicided amorphous polysilicon to metal capacitor as recited in claim 14 wherein dosage of the neutral species resulting from said implanting is substantially between 10¹⁵ per cm² and 10¹⁶ per cm².

18. The silicided amorphous polysilicon to metal capacitor as recited in claim 14 wherein the neutral species is implanted with an energy of about 100 KeV.

19. The silicided amorphous polysilicon to metal capacitor as recited in claim 14 wherein the neutral species is implanted to depth of about 500 to 1000 angstroms.

20. The silicided amorphous polysilicon to metal capacitor as recited in claim 14 wherein the top portion has a depth of about 500 to 1000 angstroms.

21. The silicided amorphous polysilicon to metal capacitor as recited in claim 11 wherein the amorphous polysilicon of the first plate is formed by exposing a polycrystalline silicon layer to an ion bombardment produced in a plasma enhanced chemical vapor deposition (PECVD) chamber.

22. The silicided amorphous polysilicon to metal capacitor as recited in claim 21 wherein the ion bombardment is generated from is amorphous polysilicon of the first plate is formed by exposing a polycrystalline silicon layer to an ion bombardment produced from a heavy ion carrying gas, including argon, krypton, or xenon.

22. The silicided amorphous polysilicon to metal capacitor as recited in claim 12 wherein the amorphous polysilicon of the first plate is formed by exposing a polycrystalline silicon layer to an ion bombardment produced in an etch vapor deposition (PECVD) chamber.
